(19) United States
(12) Patent Application Publication
(10) Pub. No.: US 2008/0050932 A1
(43) Pub. Date: Feb. 28, 2008

(54) Overall defect reduction for PECVD films

(75) Inventors: Annamalai Lakshmanan, Santa Clara, CA (US); Vu NT Nguyen, Santa Clara, CA (US); Sohyun Park, Santa Clara, CA (US); Ganesh Balasubramanian, Sunnyvale, CA (US); Steven Reiter, Santa Clara, CA (US); Tsutomu Kiyohara, Campbell, CA (US); Francimar Schmitt, Santa Clara, CA (US); Bok Hoen Kim, San Jose, CA (US)

Correspondence Address: PATTERSON & SHERIDAN, LLP, 3040 POST OAK BOULEVARD, SUITE 1500, HOUSTON, TX, 77056, US

(73) Assignee: APPLIED MATERIALS, INC.

(21) Appl. No.: 11/508,545

(22) Filed: Aug. 23, 2006

(51) Int. Cl. H01L 21/473

(52) U.S. Cl. 438/786; 438/788; 438/789

(57) ABSTRACT

The present invention generally provides an apparatus and method for reducing defects on films deposited on semiconductor substrates. One embodiment of the present invention provides a method for depositing a film on a substrate. The method comprises treating the substrate with a first plasma configured to reduce pre-existing defects on the substrate, and depositing a film comprising silicon and carbon on the substrate by applying a second plasma generated from at least one precursor and at least one reactant gas.

### BACKGROUND OF THE INVENTION

1. Field of the Invention

Embodiments of the present invention generally relate to an apparatus and method for depositing thin films on semiconductor substrates using chemical vapor deposition (CVD). More particularly, embodiments of the present invention relate to an apparatus and method for reducing defects on films deposited on semiconductor substrates.

2. Description of the Related Art

Semiconductor fabrication includes a series of processes used to fabricate multilayered features on semiconductor substrates. The process chambers may include, for example, substrate preconditioning chambers, cleaning chambers, bake chambers, chill chambers, chemical vapor deposition chambers, physical vapor deposition chambers, etch chambers, electrochemical plating chambers, and the like. Successful operation requires a stream of substrates to be processed among the chambers, which conducts steady state performance on each one of the stream of substrates.

During semiconductor fabrication, materials, such as oxides, e.g., carbon doped oxides, are typically deposited on a substrate in a processing chamber, such as a deposition chamber, e.g., a chemical vapor deposition (CVD) chamber. In a typical CVD process, a substrate is exposed to one or more volatile precursors flown into the CVD chamber, which react and/or decompose on the substrate surface to produce the desired deposit. Frequently, volatile by-products are also produced, and are removed by gas flow through the CVD chamber. In a plasma enhanced chemical vapor deposition (PEVCD), a plasma is generated in the CVD chamber to enhance chemical reaction rates of the precursors. PECVD processing allows deposition at lower temperatures, which is often critical in the manufacture of semiconductors.

Killer defects, such as cluster type defects, which cause failures in a semiconductor device, may be generated during semiconductor manufacturing due to contaminations and/or development of preexisting defects. Semiconductor processes, such as PECVD processes, become increasingly sensitive to defects with the continual reduction in feature size and increasing substrate and die sizes. Therefore, there is an increasing need for an apparatus and method for reducing overall defects in semiconductor processing.

### SUMMARY OF THE INVENTION

The present invention generally provides an apparatus and method for reducing defects on films deposited on semiconductor substrates.

One embodiment of the present invention provides a method for processing a substrate. The method comprises positioning the substrate in a processing chamber, treating the substrate with a first plasma configured to reduce pre-existing defects on the substrate, and depositing a film comprising carbon and silicon on the substrate by applying a second plasma generated from at least one precursor and at least one reactant gas.

Another embodiment of the present invention provides a method for processing a substrate in a PECVD chamber. The method comprises positioning the substrate in the PECVD chamber, supplying to the PECVD chamber a first reactant while applying a radio frequency power at a first level, wherein the first reactant is configured to reduce pre-existing defects on the substrate, and supplying to the PECVD chamber a second reactant while applying the radio frequency power at a second level, wherein the second reactant is configured to depositing a film on the substrate.

Yet another embodiment of the present invention provides a method for processing a substrate. The method comprises positioning the substrate in a processing chamber, performing pre-treatment to the substrate using a first plasma to reduce pre-existing defects on the substrate, depositing a film on the substrate using a second plasma generated from a precursor and a reactant gas, and purging the processing chamber using a third plasma generated from the reactant gas.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 illustrates a cross sectional view of a PECVD system in accordance with one embodiment of the present invention.

FIG. 2 schematically illustrates a load lock in accordance with one embodiment of the present invention.

FIG. 3 schematically illustrates a top view of one embodiment of a heater assembly of the load lock shown in FIG. 2.

FIG. 4 illustrates an exemplary deposition process in accordance with one embodiment of the present invention.

### DETAILED DESCRIPTION

The present invention generally provides apparatus and method for reducing overall defects in a PECVD film. The present invention comprises a load lock configured to heat substrates in an elevated temperature that leads to better particle performance. The present invention also comprises performing a plasma treatment to a substrate to be deposited and providing lower ramp up rates for precursors and power supplies.

The present invention generally provides an apparatus and method that reduces overall defects in a PECVD process. The present invention comprises a load lock configured to heating substrates in an elevated temperature that leads to better particle performance. The present invention also comprises performing a plasma treatment to a substrate to be deposited and providing lower ramp up rates for precursors and power supplies.

The invention is illustratively described below in reference to modification of a PRODUCER® SE CVD system or a DXZ® CVD system, both commercially available from Applied Materials, Inc., Santa Clara, Calif. The Producer® SE CVD system (200 mm or 300 mm) has two isolated processing regions that may be used to deposit carbon-doped silicon oxides and other materials and is described in U.S. Pat. No. 5,855,681 and No. 6,495,233, which are incorporated by reference herein. The DXZ® CVD chamber is disclosed in U.S. Pat. No. 6,364,954, issued Apr. 2, 2002, which is incorporated herein by reference.

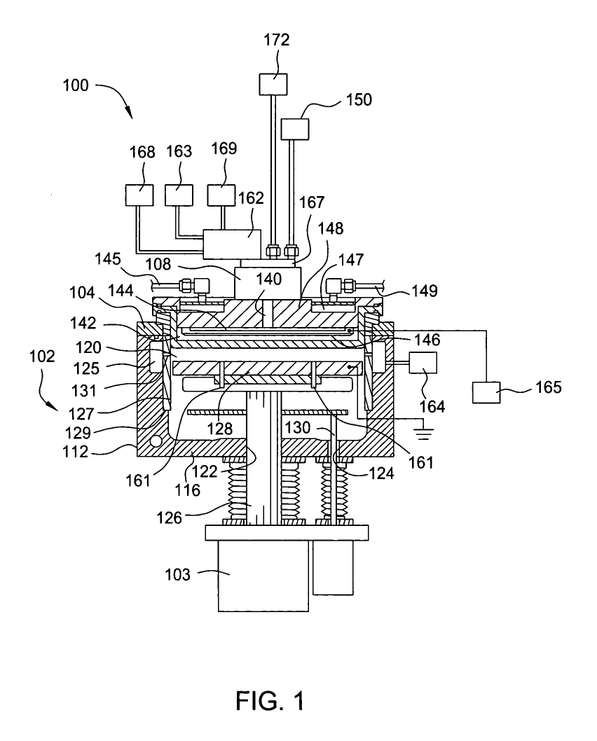

FIG. 1 illustrates a cross sectional view of a PECVD system 100 in accordance with one embodiment of the present invention. The PECVD system 100 generally comprises a chamber body 102 supporting a chamber lid 104 which may be attached to the chamber body 102 by a hinge. The chamber body 102 comprises sidewalls 112 and a bottom wall 115 defining a processing region 120. The chamber lid 104 may comprise one or more gas distribution systems 108 disposed therethrough for delivering reactant and cleaning gases into the processing region 120. A circumferential pumping channel 125 formed in the sidewalls 112 and coupled to a pumping system 164 is configured for exhausting gases from the processing region 120 and controlling the pressure within the processing region 120. Two passages 122 and 124 are formed in the bottom wall 116. A stem 126 of a heater pedestal 128 for supporting and heating a substrate being processed passes through the passage 122. A rod 130 configured to activate substrate lift pins 161 passes through the passage 124.

The heater pedestal 128 is movably disposed in the processing region 120 driven by a drive system 103 coupled to the stem 126. The heater pedestal 128 may comprise heating elements, for example resistive elements, to heat a substrate positioned thereon to a desired process temperature. Alternatively, the heater pedestal 128 may be heated by an outside heating element such as a lamp assembly. The drive system 103 may include linear actuators, or a motor and reduction gearing assembly, to lower or raise the heater pedestal 128 within the processing region 120.

A chamber liner 127, preferably made of ceramic or the like, is disposed in the processing region 120 to protect the sidewalls 112 from the corrosive processing environment. The chamber liner 127 may be supported by a ledge 129 formed in the sidewalls 112. A plurality of exhaust ports 131 may be formed on the chamber liner 127. The plurality of exhaust ports 131 is configured to connect the processing region 120 to the pumping channel 125.

The gas distribution system 108 configured to deliver reactant and cleaning gases is disposed through the chamber lid 104 to deliver gases into the processing region 120. The gas distribution system 108 includes a gas inlet passage 140 which delivers gas into a shower head assembly 142. The showerhead assembly 142 is comprised of an annular base plate 148 having a blocker plate 144 disposed intermediate to a faceplate 146. An RF (radio frequency) source 165 coupled to the shower head assembly 142 provides a bias potential to the showerhead assembly 142 to facilitate generation of a plasma between the faceplate 146 of the showerhead assembly 142 and the heater pedestal 128. The RF source 165 generally comprises a high frequency radio frequency (HFRF) power source, e.g., a 13.56 MHz RF generator, and a low frequency radio frequency (LFRF) power source, e.g., a 300 kHz RF generator. The LFRF power source provides both low frequency generation and fixed match elements. The HFRF power source is designed for use with a fixed match and regulates the power delivered to the load, eliminating concerns about forward and reflected power.

A cooling channel 147 is formed in the base plate 148 of the gas distribution system 108 to cool the base plate 148 during operation. A cooling inlet 145 delivers a coolant fluid, such as water or the like, into the cooling channel 147. The coolant fluid exits the cooling channel 147 through a coolant outlet 149.

The chamber lid 104 further comprises matching passages to deliver gases from one or more gas inlets 166 and a remote plasma source 162 to a gas inlet manifold 167 positioned on top of the chamber lid 104.

A chamber cleaning process may be performed periodically or after an idle period to reduce particle contamination in the PEVCD system 100. The chamber cleaning process may be performed using remote plasma generated from a remote plasma source positioned near a processing chamber, such as the remote plasma source 162. The remote plasma source 162 is configured to supply activated species to the processing region 120 to remove deposited materials from the interior surfaces. The remote plasma source 162 is generally connected to a precursor source 163, a carrier gas source 168 and a power source 169. During operation, a precursor gas flows into the remote plasma source 162 from the precursor source 163 at a desired flow rate. The power source 169 provides a radio frequency or microwave power to activate the precursor gas in the remote plasma source 162 to form an active species which is then flown into the processing region 120 through the gas inlet manifold 167 and the gas distribution system 108. A carrier gas, such as argon, nitrogen, helium, hydrogen or oxygen, etc, may be flown to the remote plasma source 162 and to the processing region 120 to aid the transportation of the activated species and/or to assist in the cleaning process, or help initiating and/or stabilizing the plasma in the processing region 120. In one embodiment, the power source 169 provides a radio frequency power of a wide range, e.g., 400 KHz to 13.56 MHz). The reactive gas may be selected from a wide range of options, including the commonly used halogens and halogen compounds. For example, the reactive gas may be chlorine, fluorine or compounds thereof, e.g. NF₃, CF₄, SF₆, C₂F₆, CCl₄, C₂Cl₆, etc, depending one the deposited material to be removed. The remote plasma source 162 is generally positioned close to the processing region 120 because radicals are usually short lived.

One or more processing gases may be delivered to the processing region 120 via the gas input manifold 167. Typically, there are three methods to form a gas or vapor from a precursor to be delivered to a processing region of a processing chamber to deposit a layer of desired material on a substrate. The first method is a sublimation process in which the precursor in a solid form is vaporized using a controlled process which allows the precursor to change phase from a solid to a gas (or vapor) in an ampoule. The second method is to generate a gas of a precursor by an evaporation process, in which a carrier gas is bubbled through a temperature controlled liquid precursor and the carrier gas carries away the precursor gas. In the third method, a precursor gas is generated in a liquid delivery system in which a liquid precursor is delivered to a vaporizer, and the liquid precursor changes state from a liquid to a gas by additional energy transferred to the vaporizer. A PECVD system generally comprises one or more precursor delivery systems. The PECVD system 100 may comprises one or more liquid delivery gas source 150 and one or more gas sources 172 configured to provide a carrier gas and/or a precursor gas.

The PECVD system 100 may be configured to deposit a variety of films on the substrate, e.g., a carbon doped silicon oxide film from octamethylcyclotetrasiloxane (OMCTS), a carbon doped silicon oxide film from trimethylsilane (TMS), a silicon oxide film deposited from tetraethoxysilane (TEOS), a silicon oxide film from silane (SiH₄), a carbon doped silicon oxide film from diethoxymethylsilane and alpha-terpinene, and a silicon carbide film.

Generally, a substrate to be processed in a PECVD system, such as the PECVD system 100, may be preheated and/or cooled down in a load lock. In one embodiment, a load lock may be maintained at the same vacuum or pressure level as the PECVD chamber and in selective fluid communication with a PECVD chamber via a valve, such as a slit valve. In another embodiment, a load lock and a PECVD chamber may be both coupled to a transfer chamber having a transfer robot positioned therein. Substrates may be transferred between the transfer chamber and the load lock by the transfer robot. Substrates may be heated up and cooled down in the load lock therefore spend less time in a PECVD chamber hence increase system throughput.

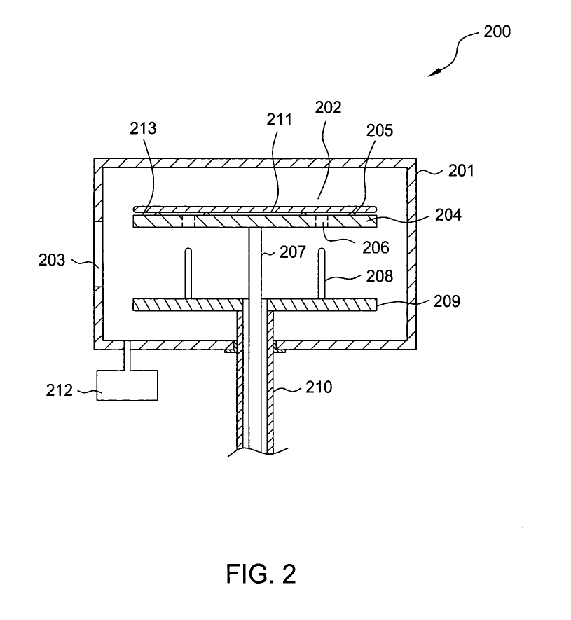

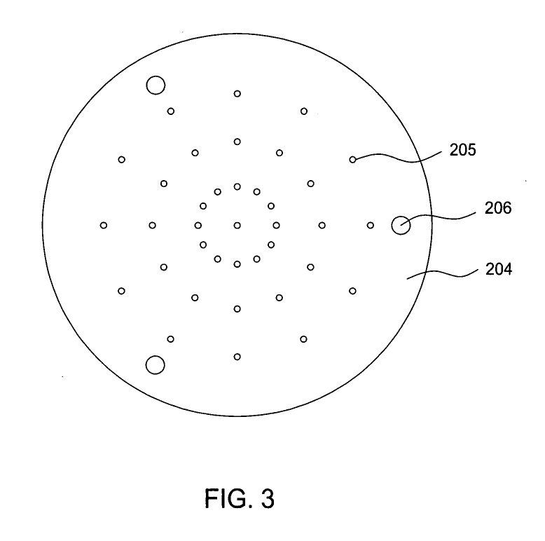

FIG. 2 schematically illustrates a load lock 200 in accordance with one embodiment of the present invention. The load lock 200 comprises a chamber body 201 defining a chamber volume 202 configured to retain a substrate 211 prior to and or after a deposition process. A slit valve 203 may be disposed on the chamber body 201 for transferring substrates in and out the chamber volume 202. A pumping system 212 may be in selective fluid communication with the chamber volume 202 to sustain a desired pressure in the chamber volume 202. A heater assembly 204 configured to support and heat the substrate is generally disposed in the chamber volume 202. In one embodiment, the heater assembly 204 may be a ceramic heater having resistive heating elements formed therein. A plurality of standoffs 205 are disposed on a top surface 213 of the heater assembly 204 and configured to contact and support the substrate 211 with a reduced contact area. In one embodiment, the plurality of standoffs 205 may be made from materials that are not likely to generate particles in contact. In another embodiment, the plurality of standoffs 205 may have similar thermal conductivity to the air between the substrate 211 and the top surface 213, therefore, providing uniform heating effect. At least three through holes 206 may be formed in the heater assembly 204 providing passages for lifting pins 208 disposed on a lifting plate 209. FIG. 3 schematically illustrates a top view of one embodiment of the heater assembly 204. The lifting plate 209 is vertically movable in relation to the heater assembly 204 so that the substrate 211 may be picked up from the heater assembly 204 by the lifting pins 208 and dropped on the heater assembly 204 by the lifting pins 208. In one embodiment, the heater assembly 204 may be supported by a post 207 disposed in a central aperture 210 formed in the lifting plate 209.

Deposition processes performed in a PECVD system, such as the PECVD system 100, becomes increasingly sensitive to defects with the continual reduction in feature size and increasing substrate and die sizes. The present invention provides a variety of methods to be used alone or in combination for reducing defects during a PECVD deposition process. The exemplary methods comprising preheating substrates at an elevated temperature, pre-treating substrates in a plasma, using a lowered radio frequency (RF) power in a seasoning process, using lower ramp up rates for supplying precursors, and performing a plasma purge after a deposition step. The methods set forth in the present invention may be used alone or in combination and will be described in detail.

### Pre-Heat a Substrate

In the state of the art PECVD process, a substrate is generally positioned in a load lock prior to loading into a PECVD chamber for the PECVD process. Generally, the substrates is initially introduced to vacuum and kept at a temperature less than about 75° C. in the load lock.

Observation has shown that pre-existing defects, such as mobile particles, on a substrate would act as nucleation sites for reactive precursor species and lead to formation of defects much larger than the pre-existing defects during PECVD deposition. The later formed defects are likely to have a size larger than 10 micrometer and become killer defects for devices formed in the substrates. When a substrate is heated in an elevated temperature, for example over 100° C., mobile particles on the substrate may be desorbed out of the surface. In one embodiment of the present invention, substrates are pre-heated in a load lock at an elevated temperature for a period of time to reduce overall defects generated on PECVD films deposited thereafter.

Pre-heating a substrate for a period of time may be used to reduce cluster type of defects during deposition of a variety of films on the substrate, e.g., a carbon doped silicon oxide film from octamethylcyclotetrasiloxane (OMCTS), a carbon doped silicon oxide film from trimethylsilane (TMS), a silicon oxide film deposited from tetraethoxysilane (TEOS), a silicon oxide film from silane (SiH₄), a carbon doped silicon oxide film from diethoxymethylsilane and alpha-terpinene, and a silicon carbide film.

In one embodiment, a substrate is heated in a load lock with a temperature about 300° C. for about 2-3 minutes prior to depositing a carbon doped silicon oxide film from octamethylcyclotetrasiloxane (OMCTS) to reduce overall defectivity of the carbon doped silicon oxide film. Production results have shown that the number of cluster-type defects, also known as grape defects or popcorn defects, that grown during CVD deposition has been drastically reduced when the substrate is heated above about 100° C. in a load lock prior to the deposition process.

Moreover, using an elevated load lock temperature also reduces overall defect sizes on the deposition films regardless of the number of pre-existing defects on the substrates. Deposition results have shown that the number of defects larger than 0.5 micrometer is reduced by heating the load lock in an elevated temperature.

Additionally, pre-heating the substrate in a load lock having an elevated temperature also reduces mechanical defects which are added during substrate handling in the PECVD system. Mechanical defects may be counted by subtracting the pre-existing defects from the total defects observed. For example, when the temperature of the load lock is set a 75° C., there are average more than 200 mechanical defects larger than 0.12 micrometer added to a substrate. The mechanical defects are possibly due to rubbing between the chamber body and a slit valve connecting the chamber and the load lock. The average number of mechanical defects larger than 0.12 micrometer reduces to less than 10 when the load lock temperature is set to about 300° C.

### Plasma Pre-Treatment

In one embodiment of the present invention, a plasma pre-treatment is performed in a PECVD chamber to a substrate prior to a deposition step. The plasma pretreatment may be carried out using a helium plasma. Other gases, such as for example argon, nitrogen, oxygen, and nitrous oxide, may also be used in the plasma pre-treatment process. Process results have shown that a plasma pre-treatment to a substrate being processed reduces the number of defects in the film deposited thereafter. The reduction of number of defects may because the plasma pre-treatment reduces nucleation sites for generating defects on the substrate.

In one embodiment, the plasma pretreatment may be followed by a pumping step to get rid of the plasma used in the plasma pretreatment prior to the deposition step. In another embodiment, the plasma for the plasma pretreatment may be followed by the plasma for the deposition step directly.

The plasma pretreatment of the present invention may be used with deposition of a variety of films on the substrate, e.g., a carbon doped silicon oxide film from octamethylcyclotetrasiloxane (OMCTS), a carbon doped silicon oxide film from trimethylsilane (TMS), a silicon oxide film deposited from tetraethoxysilane (TEOS), a silicon oxide film from silane (SiH₄), a nitride film from silane (SiH₄), a carbon doped silicon oxide film from diethoxymethylsilane and alpha-terpinene, and a silicon carbide film.

### EXAMPLE I

A plasma pretreatment of the present invention is performed for a PECVD deposition process for depositing a carbon doped silicon oxide film from octamethylcyclotetrasiloxane (OMCTS) using a PRODUCER® SE twin chamber, which comprises two processing chambers similar to the PECVD system 100 of FIG. 1. The detailed description of the PRODUCER® SE twin chamber may be found in U.S. Pat. No. 5,855,681 and No. 6,495,233, which are incorporated by reference herein.

The plasma pretreatment is performed at about 5 Torr and a chamber temperature of 350° C. for about 10 seconds to about 30 seconds. The high frequency radio frequency (HFRF) power is turned on to be at about 300 W to generate a plasma. The low frequency radio frequency (LFRF) power is turned off. The spacing between the faceplate and the heater pedestal is about 450 mils. The flowing processing gases and flow rate are used:

Oxygen, at 900 sccm for each chamber.

### Plasma Purge after Deposition

In one embodiment of the present invention, a plasma purge step may be performed after a deposition step has been performed to a substrate in a PECVD chamber. During a deposition step, one or more precursor and one or more reactant gases are generally supplied to the PECVD chamber while the radio frequency power is turned on to generate plasma for deposition. The precursor is generally turned off when the deposition step is completed. However, there is usually residual precursor in the gas line downstream of the liquid flow meter for liquid precursors and/or mass flower meter for gas precursors. Pumping the chamber is usually not enough to get rid of the residual precursors. The residual precursor is likely to condense on the chamber walls or on the substrate becoming source of particle contamination.

The plasma purge of the present invention involves burning out any residual precursor in the system. In one embodiment, the plasma purge may be performed by providing the radio frequency power continuously after the deposition step and adjusting flow rate of the reactant gas after turning off the precursor so that there is minimal throttle valve movement. The radio frequency power generates a plasma from the reactant gas reacts with the residual precursor. In one embodiment, spacing, temperature and pressure in the PECVD chamber maintain substantially the same values in the deposition step and the plasma purge step. In one embodiment, the plasma purge may be performed until the residual precursor reacts out. The time for the plasma purge step may vary depending on length of the gas line supplying the precursor. In one embodiment, the duration for the plasma purge is about 2 seconds.

The plasma purge of the present invention may be used with deposition of a variety of PECVD films and low k films on the substrate, e.g., a carbon doped silicon oxide film from octamethylcyclotetrasiloxane (OMCTS), a carbon doped silicon oxide film from trimethylsilane (TMS), a silicon oxide film deposited from tetraethoxysilane (TEOS), a silicon oxide film from silane (SiH₄), a silicon nitride film from silane (SiH₄), a carbon doped silicon oxide film from diethoxymethylsilane and alpha-terpinene, and a silicon carbide film.

### EXAMPLE II

A plasma purge of the present invention is performed for a PECVD deposition process for depositing a carbon doped silicon oxide film from octamethylcyclotetrasiloxane (OMCTS) using a PRODUCERS SE twin chamber, which comprises two processing chambers similar to the PECVD system 100 of FIG. 1. The objective of the PECVD deposition step is to deposit a carbon doped silicon oxide film with a thickness of 5000 angstrom and a dielectric value of 3.0.

The deposition step is performed at about 5 Torr and a chamber temperature of 350° C. for about 45 seconds. The high frequency radio frequency (HFRF) power (about 13.56 Hz) is turned on to be at about 500 W. The low frequency radio requency (LFRF) power (about 300 Hz) is turned on to be at about 125 W. The spacing between the faceplate and the heater pedestal is about 350 mils. The flowing processing gases and flow rate are used:

OMCTS, at 2700 mgm;

Oxygen, at 160 sccm; and

Helium, at 1000 sccm.

The plasma purge following the above deposition step is performed at about 5 Torr and a chamber temperature of 350° C. for about 2 seconds. The high frequency radio frequency (HFRF) power is turned on to be at about 100 W to generate a plasma. The low frequency radio requency (LFRF) power is turned off. The spacing between the faceplate and the heater pedestal is about 350 mils. The pressure, chamber temperature and the spacing remain the same as in the deposition step. The flowing processing gases and flow rate are used:

Oxygen, at 375 sccm; and

Helium, at 1125 sccm.

In the plasma purge step, the precursor OMCTS is turned off, the flow rates of oxygen and helium are increased to keep the total flow rate the same as in the deposition step such that there is minimal throttle valve movement.

The plasma purge step is configured to react out residual precursors and improve particle performance of the system. It should be noted that deposition also happens during plasma purge as the result of reaction between the reactants and the residual precursor. In Example II, an oxide film of about 100 angstrom with a dielectric value of 3.5 is deposited above the film deposited during the deposition step. The change of dielectric value is due to the changed ratio of precursor and the reactant. However, the deposition from plasma purge generally has no effect on the device formed on the substrate because a polishing step is generally performed after the deposition. A deposition step usually removes about 300 to 400 angstrom of a substrate surface layer. Therefore, the deposition from the plasma purge will remove the deposition completely.

### Lowered Ramp Up Rate

In one embodiment of the present invention, a lowered ramp up rate is applied to reduce cluster type defects during a PECVD deposition. The lowered ramp up rate may be applied to at least one of the flow rate of precursors, the flow rate of reactant gas, the power to the radio frequency power, or the combinations thereof. The lowered ramp up rate may be applied at the beginning of the deposition step, and/or the transition between the deposition step and the plasma purge step.

During a deposition of a carbon doped silicon oxide film from octamethylcyclotetrasiloxane (OMCTS), the formation of cluster type defects may be related to the ratio of OMCTS and oxygen. When the molar ratio of OMCTS/Oxygen is greater than about 1.56, cluster type defects form. Therefore, to lower the ratio of OMCTS/Oxygen is favorable for reduction of cluster type defects. The desired molar ratio of OMCTS/Oxygen is in the range of from about 0.28 to about 1.56.

At the beginning of a deposition process, the default ramp up rate for a precursor, such as OMCTS, is about 5000 mgm per second. At this default ramp up rate, there are chances for the precursor flow rate to be overshooting leading to precursor/reactant ratio, such as OMCTS/Oxygen ratio, therefore, causing cluster type defects to form during a deposition. Thus, lowering the ramp up rate affords more controllable precursor/reactant ratio, therefore, reducing the formation of cluster type defects. Furthermore, the ramp up rate of reactant gas may also be lowered to afford better control of the precursor/reactant ratio.

Additionally, it is also desirable to lower the ramp up rate for the radio frequency power used in the deposition process, especially when turning off and/or reducing the power supply at the end of the deposition and/or at the transition between the deposition step and the plasma deposition. When using a lowered ramp up rate to the radio frequency power supply, unwanted phenomena, such as arcing, sparking and/or eddie current, may be avoid, therefore, avoiding damage to the devices formed on the substrate and increasing deposition uniformity.

### EXAMPLE III

A PECVD deposition process for depositing a carbon doped silicon oxide film from octamethylcyclotetrasiloxane (OMCTS) using a PRODUCER® SE twin chamber, which comprises two processing chambers similar to the PECVD system 100 of FIG. 1.

The deposition may be performed by setting up parameters in the following range:

Temperature: about 200° C.-about 550° C.

Pressure: about 2 torr-about 8 torr

Spacing: about 200 mils-about 1200 mils

HFRF power: about 100 W-about 1000 W

LFRF power: about 0 W-500 W

OMCTS flow rate: about 1000 mgm-about 5000 mgm

Helium flow rate: about 500 sccm-about 5000 sccm

Oxygen flow rate: about 100 sccm-about 1000 sccm

The ramp up rate for of the parameters may be set to the following values:

HFRF power: about 100 W/s-about 500 W/s

LFRF power: about 50 W/s-200 W/s

OMCTS flow rate: about 300 mgm/s-about 1500 mgm/s

Helium flow rate: about 200 sccm/s-about 2000 sccm/s

Oxygen flow rate: about 50 sccm/s-about 500 sccm/s.

### Seasoning with Lower RF Power

Chamber seasoning is commonly practiced in PECVD process after a periodically performed chamber cleaning process. When a PECVD chamber has been sufficiently cleaned of the process gases and the cleaning by-products have been exhausted out of the chamber, a seasoning step is performed to deposit a film onto components of the chamber forming the processing region to seal remaining contaminants therein and reduce the contamination level during process. A seasoning process generally comprises depositing a seasoning film to coat the interior surfaces defining the processing region in a chamber in accordance with the subsequent deposition process recipe.

The seasoning film may be deposited on the chamber interior surface using gas mixtures identical to the gas mixtures used in the deposition processes performed in the chamber after the seasoning process. During the seasoning process, a precursor gas, an oxidation gas and a carrier gas may be flown into the chamber where a radio frequency source provides radio frequency energy to activate the precursor gas and enables a deposition. A detailed description of a seasoning may be found in the U.S. patent application Ser. No. 10/816,606, filed on Apr. 2, 2004, published on Oct. 13, 2005 as United States Patent Application Publication No: US 2005/0227499, entitled “Oxide-like Seasoning for Dielectric Low K Films”, which is incorporated herein as reference.

In one embodiment of the present invention, a seasoning process with lowered radio frequency power level(s) is applied for reduction of cluster type defects in the deposition film. It is shown that the adhesion of the seasoning film is related to the carbon contents in the seasoning film. Seasoning films with lower carbon contents are more adhesive, therefore, better for contamination control. FTIR (Fourier Transform Infrared Spectroscopy) of seasoning films have shown that the seasoning films deposited at lower RF power levels have lower carbon contents and higher cohesive strength. In one embodiment of the present invention, both high frequency radio frequency and low frequency radio frequency powers are lowered during seasoning process. In another embodiment, only the high frequency radio frequency power is lowered, the low frequency radio frequency power level remains the same. In another embodiment, the high frequency radio frequency power level is lowered while the low frequency radio frequency power is turned off.

The flow rates of different gases used in the seasoning process with lowered RF power may be adjusted to maintain the same deposition rate as in a traditional seasoning process. This allows a desired seasoning film to be formed within the same time period as of in the traditional seasoning process, hence, avoiding particle generation. In one embodiment, the seasoning process may be performed for about 10 seconds while the deposition rate is maintained at between about 1000 angstrom/minute to about 3000 angstrom/minute.

In another embodiment, ratio of different gases in the gas mixture used for the seasoning process is adjusted to get a seasoning film made of an oxide product and to avoid carbon incorporation in the seasoning film.

### EXAMPLE IV

### Traditional Seasoning Process

A seasoning layer is deposited on the interior surface of the chamber for a PECVD deposition process for depositing a carbon doped silicon oxide film from octamethylcyclotetrasiloxane (OMCTS). The chamber pressure is at about 5 Torr and a chamber temperature of 350° C. The seasoning process is performed for about 10 seconds. The spacing is about 450 mils. The flowing processing parameters are used:

HFRF, at about 1000 W;

LFRF, at about 150 W;

OMCTS, at 1300 sccm;

Oxygen, at 900 sccm;

Helium, at 2500 sccm.

### EXAMPLE V

### Seasoning Process with Lowered Power Level

A seasoning layer is deposited on the interior surface of the chamber for the same purpose of Example IV. The chamber pressure is at about 5 Torr and a chamber temperature of 350° C. The seasoning process is performed for about 10 seconds. The spacing is about 450 mils. The flowing processing parameters are used:

HFRF, at about 500 W;

LFRF, at about 150 W;

OMCTS, at 900 sccm;

Oxygen, at 900 sccm;

Helium, at 1000 sccm.

The properties of the seasoning films are compared in Table I. The examples shown that the seasoning film deposited with a lowered power level has lower carbon contents and better cohesive strength.

TABLE I

| | Seasoning | Seasoning |
|---|---|---|
| | Film from | Film from |
| | Example IV | Example V |
| Stress for deposition at 350° C. | −185 | −7 |
| (MPa) | | |
| Stress for deposition at 150° C. | −10 | 22 |
| (MPa) | | |
| Density (g/cc) | 1.97 ± 0.02 | 2.03 ± 0.02 |
| Hardness (GPa) at 1 μm | 3.54 ± 0.06 | 3.20 ± 0.01 |
| Modulus (GPa) at 1 μm | 29.28 ± 0.39 | 30.84 ± 0.09 |
| Cohesive Strength (kPa) | 3.42 | 15.69 |
| Wetting Angle | 71.7° | 65° |
| Porosity | 2% | 3% |
| —OH/Si—O—Si (area ratio × 1000) | 150.02 | 320.74 |
| Si—CH3/Si—O—Si (area ratio × 1000) | 6.65 | 2.15 |
| Si—(CH3)2/Si—O—Si | 80.58 | 42.07 |
| (area ratio × 1000) | | |
| Si/C/O/H (RBS, HFS)(%) | 23/10/46/21 | 26/5/54/15 |
| HRFR/OMCTS (W/mgm) | 0.77 | 0.56 |

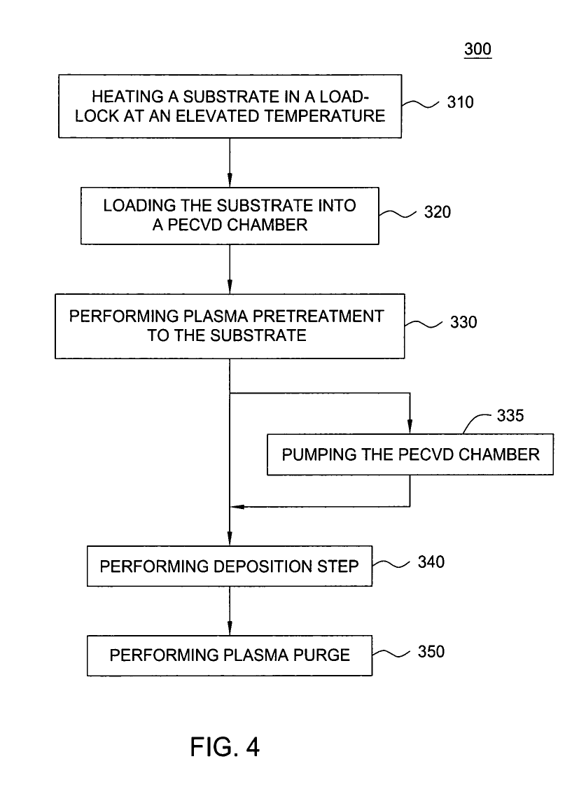

FIG. 4 illustrates an exemplary deposition process 300 in accordance with one embodiment of the present invention.

In step 310 of the deposition process 300, a substrate is heated in a load lock at an elevated temperature for a predetermined period of time. Mobile particles on the substrate may be adsorbed out of the substrate surface during the heating process.

In step 320 of the deposition process 300, the substrate is transferred, generally by a robot, from the load lock to a PECVD chamber. A slit valve may be disposed between the load lock and the PECVD chamber and configured to allow the substrate to be transferred between the load lock and the PECVD chamber.

In step 330 of the deposition process 300, a plasma pretreatment is performed to the substrate. The plasma pretreatment is configured to reduce nucleation sites from the substrate.

In step 340 of the deposition process 300, a deposition step, or the main deposition step, is performed generally by following in one or more desired precursor and corresponding reactant gas and carrier gas and generating a plasma in the PECVD chamber. In one embodiment, lowered ramp up rates may be applied to one or more process parameters at the beginning and/or the end of step 340.

Optionally, a step 335 may be performed between the step 330 and step 340. In step 335, the PECVD chamber is pumped to exhaust the plasma and/or reactant gases used in the plasma pretreatment prior to the main deposition step.

In step 350 of the deposition process 300, a plasma purge is performed. The plasma purge is configured to “burn out” the residual precursor and reduce precursor condensation in the PECVD chamber and on the substrate. In one embodiment, lowered ramp up rates are applied to one or more process parameters during the transition from step 340 to step 350.

It should be noted that the defect reducing methods set forth in the present invention may be used alone or in combination. A person skilled in the art may use different combination of the defect reducing methods in a particular deposition process to reduce defects.

While the foregoing is directed to embodiments of the present invention, other and further embodiments of the invention may be devised without departing from the basic scope thereof, and the scope thereof is determined by the claims that follow.

1. A method for processing a substrate, comprising:
positioning the substrate in a processing chamber;
treating the substrate with a first plasma configured to reduce pre-existing defects on the substrate; and
depositing a film comprising silicon and carbon on the substrate by applying a second plasma generated from at least one precursor and at least one reactant gas.

2. The method of claim 1, wherein the first plasma is generated from at least one reactant gas selected from helium (He), argon (Ar), nitrogen (N₂), oxygen (O₂), and nitrous oxide (N₂O).

3. The method of claim 1, further comprising, after depositing the film, purging the at least one precursor with a third plasma.

4. The method of claim 1, wherein depositing the film comprises controlling ramp up rate of at least one process parameter.

5. The method of claim 3, wherein purging the at least one precursor comprises:
adjusting a flow rate of the at least one reactant gas and adjusting a radio frequency power level while turning off the at least one precursor.

6. The method of claim 5, wherein the flow rate of the at least one reactant gas is adjusted to minimize movement of a throttle valve of the processing chamber while the at least one precursor is turning off.

7. The method of claim 1, wherein treating the substrate and depositing the film are performed continuously without pumping out the first plasma in the processing chamber.

8. The method of claim 1, further comprising, prior to positioning the substrate in the processing chamber, heating the substrate in a load lock at an elevated temperature for a sufficient time to remove one or more mobile particles on the substrate surface.

9. The method of claim 8, wherein the elevated temperature is above about 100° C.

10. The method of claim 1, wherein the film is at least one film selected from a carbon doped silicon oxide film from octamethylcyclotetrasiloxane (OMCTS), a carbon doped silicon oxide film from trimethylsilane (TMS), an oxide film deposited from tetraethoxysilane (TEOS), an oxide film from silane (SiH4), a nitride film from silane (SiH4), a carbon doped silicon oxide film from diethoxymethylsilane and alpha-terpinene, and a silicon carbide film.

11. A method for processing a substrate in a PECVD chamber, comprising:
positioning the substrate in the PECVD chamber;
supplying to the PECVD chamber a first reactant while applying a radio frequency power at a first level, wherein the first reactant is configured to reduce pre-existing defects on the substrate; and
supplying to the PECVD chamber a second reactant while applying the radio frequency power at a second level, wherein the second reactant is configured to deposit a film on the substrate.

12. The method of claim 11, wherein the first reactant gas comprises at least one reactant gas selected from helium (He), argon (Ar), nitrogen (N₂), oxygen (O₂), and nitrous oxide (N₂O).

13. The method of claim 11, further comprising prior to supplying the second reactant, pumping out the processing chamber.

14. The method of claim 11, wherein supplying the second reactant comprises ramping up the second reactant at a sufficiently low rate.

15. The method of claim 11, wherein the second reactant comprises at least one precursor, and at least one reactant gas.

16. The method of claim 15, further comprising increasing a flow rate of the at least one reactant gas, and turning off the at least one precursor while applying the radio frequency power at a third level.

17. The method of claim 16, wherein the radio frequency power is adjusted from the second level to the third level at a controlled manner.

18. A method for processing a substrate, comprising:
positioning the substrate in a processing chamber;
performing pre-treatment to the substrate using a first plasma to reduce pre-existing defects on the substrate;
depositing a film on the substrate using a second plasma generated from a precursor and a reactant gas; and
purging the processing chamber using a third plasma generated from the reactant gas.

19. The method of claim 18, further comprising, prior to positioning the substrate in the processing chamber, preheating the substrate in a load lock.

20. The method of claim 18, wherein performing pre-treatment and depositing the film are performed continuously without pumping out the processing chamber.

21. The method of claim 18, wherein depositing the film comprises:
turning on the precursor at a first sufficiently slow rate;
supplying the precursor and the reactant gas at predetermined flow rates; and
turning off the precursor at a second sufficiently slow rate.

22. The method of claim 21, wherein depositing the film further comprises,
adjusting a radio frequency power level at a sufficiently slow rate.

23. The method of claim 18, wherein the film is at least one film selected from a carbon doped silicon oxide film from octamethylcyclotetrasiloxane (OMCTS), a carbon doped silicon oxide film from trimethylsilane (TMS), an oxide film deposited from tetraethoxysilane (TEOS), an oxide film from silane (SiH4), a nitride film from silane (SiH4), a carbon doped silicon oxide film from diethoxymethylsilane and alpha-terpinene, and a silicon carbide film.
